(19) United States
(12) Patent Application Publication
(10) Pub. No.: US 2025/0105845 A1
(43) Pub. Date: Mar. 27, 2025

(54) LEVEL SHIFTER

(71) Applicant: LAPIS Technology Co., Ltd., Yokohama (JP)

(72) Inventor: Takeshi WAKAMATSU, Yokohama (JP)

(73) Assignee: LAPIS Technology Co., Ltd., Yokohama (JP)

(21) Appl. No.: 18/896,809

(22) Filed: Sep. 25, 2024

(30) Foreign Application Priority Data
Sep. 27, 2023 (JP) 2023-166397

(51) Int. Cl. H03K 19/0185

(52) U.S. Cl. CPC H03K 19/018521

(57) ABSTRACT

A level shifter includes: an input stage circuit receiving a relatively low level input signal, and an output stage circuit converting the input signal into a relatively high level signal and outputting the signal. The output stage circuit includes: first and second transistors, to which complementary signals generated according to the input signal are respectively input; a first switch circuit, having a main path connected with the first transistor, entering an ON-state with the second transistor entering the ON-state, and entering an OFF-state with the second transistor entering the OFF-state; and a second switch circuit, having a main path connected with the second transistor, entering the ON-state with the first transistor entering the ON-state, and entering the OFF-state with the first transistor entering the OFF-state. Regarding ON-resistance, the first switch circuit is greater than the first transistor, and the second switch circuit is greater than the second transistor.

### CROSS-REFERENCE TO RELATED APPLICATION

This application claims priority under 35 USC 119 from Japanese Patent application No. 2023-166397 filed on Sep. 27, 2023, the disclosure of which is incorporated by reference herein.

### BACKGROUND

### Technical Field

The disclosure relates to a level shifter.

### Description of Related Art

As technologies related to level shifters, the following technologies are known. Japanese Patent Application Laid-open No. 2008-131457 describes a level shifter circuit. The level shifter circuit includes: a first voltage conversion circuit, generating a drive voltage lower than a first power voltage supplied from a first power line and corresponding to the first power voltage, generating a complementary signal corresponding to an input signal using the drive voltage, and outputs the complementary signal; a second voltage conversion circuit, generating and outputting a signal corresponding to the voltage of the complementary signal output by the first voltage conversion circuit by using a second power voltage supplied from a second power line; and an output latch circuit, holding a signal according to the voltage of the signal output by the second voltage conversion circuit.

Japanese Patent Application Laid-open No. 2001-24502 describes a voltage level shifter including first to fourth transistors of a first conductivity type. The first and second transistors are connected in series between first and second power inputs. The control electrode of the second transistor is connected to a first input for receiving a direct input signal. The third and fourth transistors are connected in series between the first and second power inputs. The control electrode of the fourth transistor is connected to a second input for receiving a complementary input signal. The control electrode of the first transistor is connected to the output electrode of the third transistor and the common electrode of the fourth transistor. The control electrode of the third transistor is connected to the output electrode of the first transistor and the common electrode of the second transistor.

Japanese Patent Application Laid-open No. 2003-17996 describes a level shift circuit including a level shifter that converts a low-voltage signal to a high-voltage signal. The level shifter includes an input transistor to which a low-voltage signal is input, and generates an output signal of the level shifter according to the ON/OFF state of the input transistor. The level shift circuit includes a means for determining an input signal to the input transistor of the level shifter in the case where a high-voltage power supply is applied before a low-voltage power supply.

### PRIOR ART DOCUMENT(S)

### Patent Document(s)

[Patent Document 1] Japanese Laid-open No. 2008-131457
[Patent Document 2] Japanese Laid-open No. 2001-24502
[Patent Document 3] Japanese Laid-open No. 2003-17996

In a level shifter including an input stage circuit to which a relatively low-level input signal is input and an output stage circuit that converts the input signal to a relatively high-level signal and outputs the converted signal, if the level of the power voltage supplied to the input stage circuit decreases to about the level of the threshold voltage of the transistor forming the output stage circuit, an appropriate output signal may not be obtained.

The disclosure provides a level shifter. An appropriate output signal is provided in the level shifter including an input stage circuit to which a relatively low-level input signal is input and an output stage circuit that converts the input signal to a signal of relatively high-level and outputs the signal, even in the case where the level of the power voltage supplied to the input stage circuit decreases.

### SUMMARY

A level shifter according to the disclosure includes: an input stage circuit and an output stage circuit. The input stage circuit receives an input signal of a relatively low level, and the output stage circuit converts the input signal into a signal of a relatively high level and outputs the signal. The output stage circuit includes: a first transistor and a second transistor, to which complementary signals generated in accordance with the input signal are respectively input; a first switch circuit, having a main path connected with the first transistor, entering an ON-state in accordance with the second transistor entering the ON-state, and entering an OFF-state in accordance with the second transistor entering the OFF-state; and a second switch circuit, having a main path connected with the second transistor, entering the ON-state in accordance with the first transistor entering the ON-state, and entering the OFF-state in accordance with the first transistor entering the OFF-state. An ON-resistance of the first switch circuit is greater than an ON-resistance of the first transistor, and an ON-resistance of the second switch circuit is greater than an ON-resistance of the second transistor.

### BRIEF DESCRIPTION OF THE DRAWINGS

FIG. 1 is a circuit diagram showing an example of a configuration of a level shifter according to an embodiment of the disclosure.

FIG. 2 is a circuit diagram showing an example of a configuration of a level shifter according to a comparative example.

FIG. 3 is a circuit diagram showing an example of a configuration of a level shifter according to another embodiment of the disclosure.

### DETAILED DESCRIPTION

According to the disclosure, in a level shifter including an input stage circuit to which a relatively low-level input signal is input and an output stage circuit that converts the input signal to a relatively high-level signal and outputs the converted signal, it is possible to obtain an appropriate output signal even in the case where the level of the power voltage supplied to the input stage circuit decreases.

The following describes an example of an embodiment of the disclosure with reference to the drawings. In each drawing, the same reference numerals are assigned to identical or equivalent components and parts, and duplicate explanations are omitted.

### First Embodiment

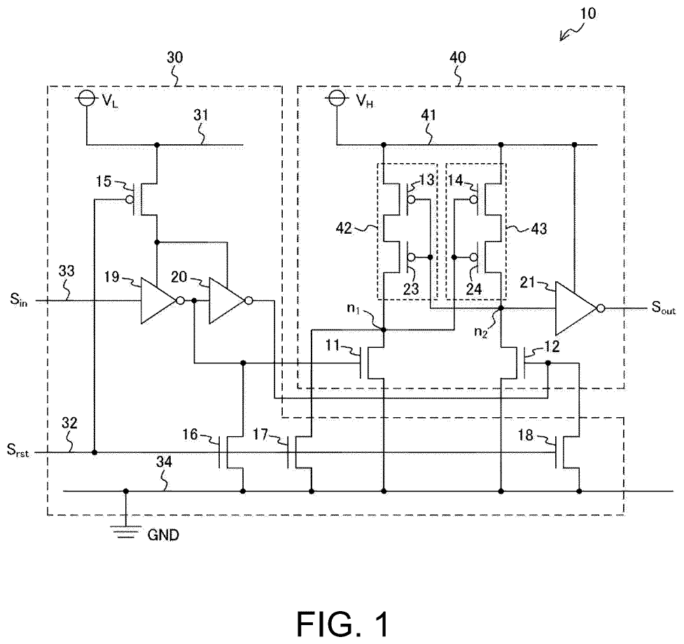

FIG. 1 is a circuit diagram showing an example of a configuration of a level shifter 10 according to a first embodiment of the disclosure. The level shifter 10 includes an input stage circuit 30 and an output stage circuit 40. An input signal Sᵢₙ of a relatively low level is input to the input stage circuit 30. The output stage circuit 40 converts the input signal Sᵢₙ to a signal of a relatively high level and outputs the signal as an output signal Sₒᵤₜ.

The input stage circuit 30 includes a P-channel transistor 15, N-channel transistors 16, 17, 18, and inverters 19, 20. In the transistor 15, the source is connected to a power line 31 to which a power voltage V_{L} of a relatively low level is applied, the drain is connected to the power terminals of the inverters 19 and 20, and the gate is connected to a reset input line 32 to which a reset signal Sᵣₛₜ is input.

In the inverter 19, the input terminal is connected to a signal input line 33 to which the input signal Sᵢₙ is input, and the output terminal 19 is connected to the input terminal of the inverter 20. In the inverter 20, the output terminal is connected to the gate of the transistor 12 in the output stage circuit 40. The inverters 19 and 20 are driven by the relatively low-level power voltage V_{L}.

In the transistor 16, the drain is connected to the input terminal of the inverter 20, the source is connected to a ground line 34, and the gate is connected to the reset input line 32. In the transistor 17, the drain is connected to the drain (a node n₁) of the transistor 11 in the output stage circuit 40, the source is connected to the ground line 34, and the gate is connected to the reset input line 32. In the transistor 18, the drain is connected to the gate of the transistor 12 in the output stage circuit 40, the source is connected to the ground line 34, and the gate is connected to the reset input line 32.

The output stage circuit 40 includes P-channel transistors 13, 14, N-channel transistors 11, 12, and an inverter 21. In the transistor 13, the source is connected to a power line 41 to which a power voltage V_{H} of a relatively high level is applied, the drain is connected to the source of a transistor 23, and the gate is connected to the drain (a node n₂) of the transistor 12. In the transistor 23, the drain is connected to the drain (the node n₁) of the transistor 11, and the gate is connected to the drain (the node n₂) of the transistor 12. A first switch circuit 42 is formed by the transistors 13 and 23 in cascade connection. The transistor 13 is an example of “third transistor” in the disclosure. The transistor 23 is an example of “fourth transistor” in the disclosure. The first switch circuit 42 is an example of “first switch circuit” in the disclosure.

In the transistor 14, the source is connected to the power line 41, the drain is connected to the source of the transistor 24, and the gate is connected to the drain (the node n₁) of the transistor 11. In the transistor 24, the drain is connected to the drain (the node n₂) of the transistor 12, and the gate is connected to the drain (the node n₁) of the transistor 11. A second switch circuit 43 is formed by the transistors 14 and 23 in cascade connection. The transistor 14 is an example of “fifth transistor” in the disclosure. The transistor 24 is an example of “sixth transistor” in the disclosure. The second switch circuit 43 is an example of “second switch circuit” in the disclosure.

In the transistor 11, the source is connected to the ground line 34, and the gate is connected to the output terminal of the inverter 19. In the transistor 12, the source is connected to the ground line 34, and the gate is connected to the output terminal of the inverter 20.

In the inverter 21, the power terminal is connected to the power line 41, and the input terminal is connected to the drain (the node n₂) of the transistor 12. The inverter 21 is driven by the relatively high-level power voltage V_{H}, and outputs a signal, as the output signal Sₒᵤₜ, that inverts the logic level of the signal input to the input terminal.

The input stage circuit 30 generates, by using the inverters 19 and 20, complementary signals based on the input signal Sᵢₙ input to the signal input line 33. That is, the inverter 19 outputs the signal in which the logic level of the input signal Sᵢₙ is inverted, and the inverter 20 outputs a signal with the same logic level as the input signal Sᵢₙ.

In the output stage circuit 40, the output signal of the inverter 19 is input to the gate of the transistor 11, and the output signal of the inverter 20 is input to the gate of the transistor 12. The transistors 11 and 12 operate complementarily in accordance with the complementary signals input to the transistors 11 and 12. The transistor 11 is an example of “first transistor” in the disclosure. The transistor 12 is an example of “second transistor” in the disclosure.

In the first switch circuit 42 formed by the transistors 13 and 23 in cascade connection, the main path is connected to the transistor 11, and the control terminal is connected to the node n₂. The first switch circuit 42 enters the ON-state in accordance with the transistor 12 entering the ON-state, and enters the OFF-state in accordance with the transistor 12 entering the OFF-state.

In the second switch circuit 43 formed by the transistors 14 and 24 in cascade connection, the main path is connected to the transistor 12, and the control terminal is connected to the node n₁. The second switch circuit 43 enters the ON-state in accordance with the transistor 11 entering the ON-state, and enters the OFF-state in accordance with the transistor 11 entering the OFF-state.

The first switch circuit 42 and the second switch circuit 43 operate complementarily in accordance with the ON/OFF states of the transistors 11 and 12 operating complementarily. By forming the first switch circuit 42 using the transistors 13 and 23 in cascade connection, the ON-resistance (output resistance) of the first switch circuit 42 is made greater than the ON-resistance of the transistor 11. Likewise, by forming the second switch circuit 43 using the transistors 14 and 23 in cascade connection, the ON-resistance of the second switch circuit 43 is made greater than the ON-resistance of the transistor 12. Here, the ON-resistances of the transistors 11 and 12 refers to the ON-resistance during half-ON.

The operation of the level shifter 10 is described below. Firstly, the reset operation is described. In the case of performing the reset operation in the level shifter 10, a reset signal Sᵣₛₜ of high level is input to the reset input line 32. As a result, each of the transistors 16, 17, and 18 enters the ON-state, and the transistors 11 and 12 enter the OFF-state regardless of the logic level of the input signal Sᵢₙ. With the transistor 17 entering the ON-state, the potential of the node n₁ becomes low level, so the transistors 14 and 24 enter the ON-state. Consequently, the potential of the node n₂ becomes high level, so the output signal Sₒᵤₜ output from the output terminal of the inverter 21 becomes low level. As described above, during the reset operation of the level shifter 10, in accordance with the reset signal Sᵣₛₜ of high level being input, the output signal Sₒᵤₜ of low level is output regardless of the logic level of the input signal Sᵢₙ.

Next, the operation in the case where the input signal Sᵢₙ of low level is input during the level shift operation is described. In the case of performing the level shift operation in the level shifter 10, the reset signal Sᵣₛₜ of low level is input to the reset input line 32. As a result, each of the transistors 16, 17, and 18 enters the OFF-state. In this state, when the input signal Sᵢₙ of low level is input to the signal input line 33, the inverter 19 outputs a high-level signal, which causes the transistor 11 to enter the ON-state. Additionally, the inverter 20 outputs a low-level signal, which causes the transistor 12 to enter the OFF-state. With the transistor 11 entering the ON-state and the transistor 12 entering the OFF-state, the potential of the node n₁ converges to the low level, and the potential of the node n₂ converges to the high level. Consequently, the output signal Sₒᵤₜ output from the output terminal of the inverter 21 becomes low level. As described above, during the level shift operation of the level shifter 10, in accordance with the input signal Sᵢₙ of low level being input, the output signal Sₒᵤₜ of low level is output.

Next, the operation in the case where the input signal Sᵢₙ of high level is input during the level shift operation is described. In the case of performing the level shift operation in the level shifter 10, the reset signal Sᵣₛₜ of low level is input to the reset input line 32, and the input signal Sᵢₙ of high level is input to the signal input line 33. Consequently, the inverter 19 outputs a low-level signal, which causes the transistor 11 to enter the OFF-state. Additionally, the inverter 20 outputs a high-level signal, which causes the transistor 12 to enter the ON-state. With the transistor 11 entering the OFF-state and the transistor 12 entering the ON-state, the potential of the node n₁ converges to the high level, and the potential of the node n₂ converges to the low level. Consequently, the output signal Sₒᵤₜ output from the output terminal of the inverter 21 becomes high level. As described above, during the level shift operation of the level shifter 10, in accordance with the input signal Sᵢₙ of high level being input, the output signal Sₒᵤₜ of high level is output. The level of the output signal Sₒᵤₜ output from the inverter 21 driven by the power voltage V_{H} of relatively high-level is higher than the level of the input signal Sᵢₙ input to the inverter 19 driven by the power voltage VI, of a relatively low level.

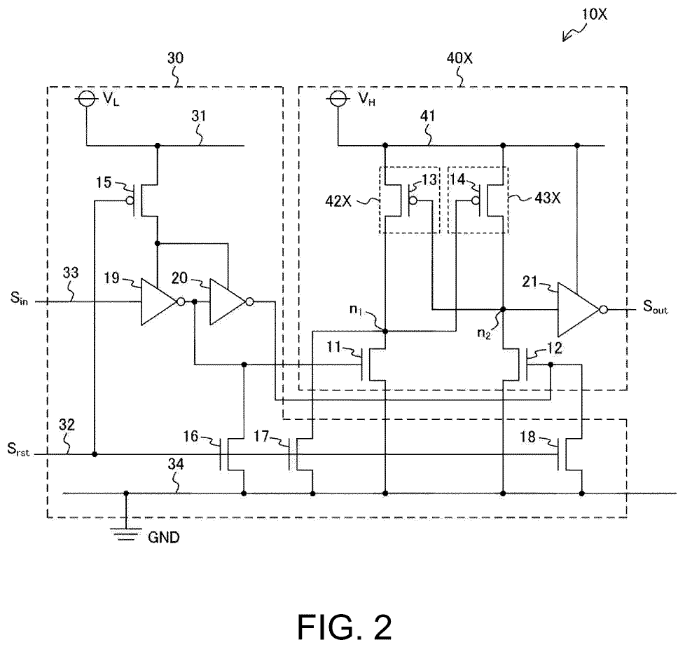

Here, FIG. 2 is a circuit diagram showing a configuration of a level shifter 10X according to a comparative example. The level shifter 10X according to the comparative example differs from the level shifter 10 (see FIG. 1) related to the embodiment of the disclosure in that, in an output stage circuit 40X, a first switch circuit 42X is only formed by the transistor 13, and a second switch circuit 43X is only formed by the transistor 14. The basic operation of the level shifter 10X according to the comparative example is the same as that of the level shifter 10 related to the embodiment of the disclosure.

In the level shifter 10X according to the comparative example, the case as follows is considered: the level of the power voltage V_{L} supplied to the input stage circuit 30 decreases to approximately the level of the threshold voltage of the transistors 11 and 12. In this case, according to the input signal Sᵢₙ, the transistor 11 or the transistor 12 enters the half-ON state, in which the ON-state is incomplete. As a result, the potential of the node n₁ or the node n₂ becomes an intermediate potential, and there is a risk that an appropriate output signal Sₒᵤₜ may not be output.

On the other hand, in the level shifter 10 related to the embodiment of the disclosure, the first switch circuit 42 is formed by the transistors 13 and 23 in cascade connection, and the second switch circuit 43 is formed by the transistors 14 and 24 in cascade connection. As a result, the ON-resistance of the first switch circuit 42 can be made greater than the ON-resistance of the transistor 11 during half-ON, and the ON-resistance of the second switch circuit 43 can be made greater than the ON-resistance of the transistor 12 during half-ON.

In the level shifter 10 related to the embodiment of the disclosure, in the case where the level of the power voltage V_{L} supplied to the input stage circuit 30 decreases to approximately the level of the threshold voltage of the transistors 11 and 12, similar to the comparative example, the transistor 11 or 12 enters the half-ON state according to the input signal Sᵢₙ.

For example, in the case where the input signal Sᵢₙ of low level is input and the transistor 11 enters the half-ON state, by making the ON-resistance of the first switch circuit 42 greater than the ON-resistance of the transistor 11 during half-ON, the potential of the node n₁ can be decreased to approximately a level where the second switch circuit 43 enters the half-ON state. With the second switch circuit 43 entering the half-ON state, the potential of the node n₂ can be increased to approximately a level where the first switch circuit 42 enters the half-OFF state. As a result, the potential of the node n₁ can eventually converge to low-level and the potential of the node n₂ can eventually converge to high-level, and the output signal Sₒᵤₜ of low level is output.

In addition, in the case where the input signal Sᵢₙ of high level is input and the transistor 12 enters the half-ON state, by making the ON-resistance of the second switch circuit 43 greater than the ON-resistance of the transistor 12 during half-ON, the potential of the node n₂ can be decreased to approximately a level where the first switch circuit 42 enters the half-ON state. With first second switch circuit 42 entering the half-ON state, the potential of the node n₁ can be increased to approximately a level where the second switch circuit 43 enters the half-OFF state. As a result, the potential of the node n₁ can eventually converge to low-level and the potential of the node n₂ can eventually converge to high-level, and the output signal Sₒᵤₜ of high level is output.

As described above, according to the level shifter 10 related to the embodiment of the disclosure, even in the case where the level of the power voltage V_{L} supplied to the input stage circuit 30 decreases to approximately the level of the threshold voltage of the transistors 11 and 12, an appropriate output signal Sₒᵤₜ can be obtained according to the input signal Sᵢₙ.

Also, by using multiple transistors in cascade connection as a means to increase the ON-resistances of the first switch circuit 42 and the second switch circuit 43, a substrate bias effect of the transistors 23 and 24 can be obtained. As a result, compared to using a single transistor as the means to increase the ON-resistances of the first switch circuit 42 and the second switch circuit 43, the effect of increasing the ON-resistance can be enhanced. Consequently, the sizes of the transistors can be reduced, making it possible to decrease the areas and the dead spaces of the first switch circuit 42 and the second switch circuit 43.

### Second Embodiment

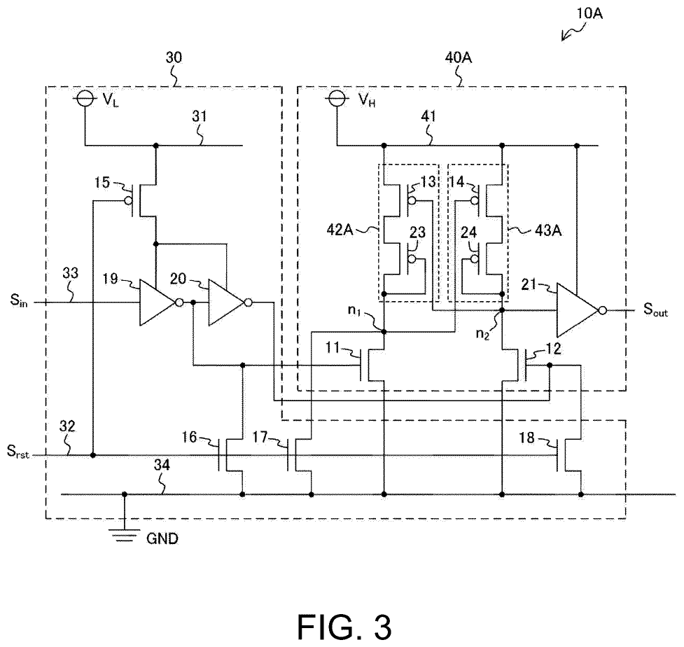

FIG. 3 is a circuit diagram showing an example of a configuration of a level shifter 10A according to a second embodiment of the disclosure. Like the level shifter 10 (see FIG. 1) related to the first embodiment, in the level shifter 10A, an output stage circuit 40A has a first switch circuit 42A formed by the transistors 13 and 23 in cascade connection, and a second switch circuit 43A formed by the transistors 14 and 24 in cascade connection. In the first switch circuit 42A, the gate of the transistor 23 is connected to the drain (the node n₁) of the transistor 11, and the gate of the transistor 24 is connected to the drain (the node n₂) of the transistor 12. In other words, the transistors 23 and 24 are each diode-connected.

By forming the first switch circuit 42A using the transistors 13 and 23 in cascade connection, the ON-resistance of the first switch circuit 42A is made greater than the ON-resistance of the transistor 11 during half-ON. Similarly, by forming the second switch circuit 43A using the transistors 14 and 24 in cascade connection, the ON-resistance of the second switch circuit 43 is made greater than the ON-resistance of the transistor 12 during half-ON.

According to the level shifter 10A related to the second embodiment, similar to the level shifter 10 related to the first embodiment, for example, in the case where the input signal Sᵢₙ of low-level is input and the transistor 11 enters the half-ON state, by making the ON-resistance of the first switch circuit 42A greater than the ON-resistance of the transistor 11 during half-ON, the potential of the node n₁ can be decreased to approximately a level that causes the second switch circuit 43A to enter the half-ON state. With the second switch circuit 43A entering the half-ON state, the potential of the node n₂ can be increased to approximately a level where the first switch circuit 42 enters the half-OFF state. As a result, the potential of the node n₁ can eventually converge to low-level, the potential of the node n₂ can eventually converge to high-level, and the output signal Sₒᵤₜ of low level is output. If the potential of the node n₁ can be decreased by the transistor 11 in the half-ON state to a potential that is lower than the potential of the drain of the transistor 13 by the threshold voltage of the transistor 23, the potential of the node n₁ can converge to low-level and the potential of the node n₂ can converge to high-level.

In addition, in the case where the input signal Sᵢₙ of high level is input and the transistor 12 enters the half-ON state, by making the ON-resistance of the second switch circuit 43A greater than the ON-resistance of the transistor 12 during half-ON, the potential of the node n₂ can be decreased to approximately a level where the first switch circuit 42A enters the half-ON state. With the first switch circuit 42A entering the half-ON state, the potential of the node n₁ can be increased to approximately a level where the second switch circuit 43A enters the half-OFF state. As a result, the potential of the node n₁ can eventually converge to low-level and the potential of the node n₂ can eventually converge to high-level, and the output signal Sₒᵤₜ of high level is output. If the potential of the node n₂ can be decreased by the transistor 12 in the half-ON state to a potential that is lower than the potential of the drain of the transistor 14 by the threshold voltage of the transistor 24, the potential of the node n₁ can converge to high-level and the potential of the node n₂ can converge to low-level.

As described above, according to the level shifter 10A related to the second embodiment of the disclosure, similar to the level shifter 10 of the first embodiment, even in the case where the level of the power voltage V_{L} supplied to the input stage circuit 30 decreases to approximately the level of the threshold voltage of the transistors 11 and 12, an appropriate output signal Sₒᵤₜ can be obtained according to the input signal Sᵢₙ.

Furthermore, according to the level shifter 10A of the second embodiment, if the potential of the node n₁ can be decreased by the transistor 11 in the half-ON state to a potential that is lower than the potential of the drain of the transistor 13 by the threshold voltage of the transistor 23, the potential of the node n₁ can converge to low-level and the potential of the node n₂ can converge to high-level, and if the potential of the node n₂ can be decreased by the transistor 12 in the half-ON state to a potential that is lower than the potential of the drain of the transistor 14 by the threshold voltage of the transistor 24, the potential of the node n₁ can converge to high-level and the potential of the node n₂ can converge to low-level. As a result, the sizes of the transistors forming the first switch circuit 42A and the second switch circuit 43A can be further reduced, making it possible to further reduce the areas and the dead spaces of the first switch circuit 42 and the second switch circuit 43.

Moreover, according to the level shifter 10A of the second embodiment, the state of the output signal Sₒᵤₜ can be fixed during the reset operation, so it is possible to use the level shifter 10A as a state-fixing circuit.

In addition to the first and second embodiments, the following appendices are disclosed.

### Appendix 1

A level shifter includes: an input stage circuit; and; an output stage circuit. The input stage circuit receives an input signal of a relatively low level, and the output stage circuit converts the input signal into a signal of a relatively high level and outputs the signal. The output stage circuit includes: a first transistor and a second transistor, to which complementary signals generated in accordance with the input signal are respectively input; a first switch circuit, having a main path connected with the first transistor, entering an ON-state in accordance with the second transistor entering the ON-state, and entering an OFF-state in accordance with the second transistor entering the OFF-state; and a second switch circuit, having a main path connected with the second transistor, entering the ON-state in accordance with the first transistor entering the ON-state, and entering the OFF-state in accordance with the first transistor entering the OFF-state. An ON-resistance of the first switch circuit is greater than an ON-resistance of the first transistor, and an ON-resistance of the second switch circuit is greater than an ON-resistance of the second transistor.

### Appendix 2

In the level shifter according to Appendix 1, the first switch circuit includes a third transistor and a fourth transistor in cascade connection, and the second switch circuit includes a fifth transistor and a sixth transistor in cascade connection.

### Appendix 3

In the level shifter according to Appendix 2, gates of the third transistor and the fourth transistor are connected with a drain of the second transistor, and gates of the fifth transistor and the sixth transistor are connected with a drain of the first transistor.

### Appendix 4

In the level shifter according to Appendix 2, a gate of the third transistor is connected with a drain of the second transistor, a gate of the fourth transistor is connected with a drain of the first transistor, a gate of the fifth transistor is connected with the drain of the first transistor, and a gate of the sixth transistor is connected with the drain of the second transistor.

### Appendix 5

In the level shifter according to any one of Appendices 1 to 4, the input stage circuit includes a first inverter and a second inverter that are in cascade connection and driven by a power voltage of a relatively low level. The input signal is input to the first inverter, an output signal of the first inverter is input to the second inverter and the first transistor, an output signal of the second inverter is input to the second transistor, the output stage circuit comprises a third inverter driven by a power voltage of a relatively high level, and a signal generated at a connection point between the second transistor and the second switch circuit is input to the third inverter.

What is claimed is:

1. A level shifter, comprising: an input stage circuit; and an output stage circuit, wherein the input stage circuit receives an input signal of a relatively low level, and the output stage circuit converts the input signal into a signal of a relatively high level and outputs the signal, the output stage circuit comprising:
a first transistor and a second transistor, to which complementary signals generated in accordance with the input signal are respectively input;
a first switch circuit, having a main path connected with the first transistor, entering an ON-state in accordance with the second transistor entering the ON-state, and entering an OFF-state in accordance with the second transistor entering the OFF-state; and
a second switch circuit, having a main path connected with the second transistor, entering the ON-state in accordance with the first transistor entering the ON-state, and entering the OFF-state in accordance with the first transistor entering the OFF-state,
wherein an ON-resistance of the first switch circuit is greater than an ON-resistance of the first transistor, and an ON-resistance of the second switch circuit is greater than an ON-resistance of the second transistor.

2. The level shifter as claimed in claim 1, wherein the first switch circuit comprises a third transistor and a fourth transistor in cascade connection, and
the second switch circuit comprises a fifth transistor and a sixth transistor in cascade connection.

3. The level shifter as claimed in claim 2, wherein gates of the third transistor and the fourth transistor are connected with a drain of the second transistor, and
gates of the fifth transistor and the sixth transistor are connected with a drain of the first transistor.

4. The level shifter as claimed in claim 2, wherein a gate of the third transistor is connected with a drain of the second transistor,
a gate of the fourth transistor is connected with a drain of the first transistor,
a gate of the fifth transistor is connected with the drain of the first transistor, and
a gate of the sixth transistor is connected with the drain of the second transistor.

5. The level shifter as claimed in claim 1, wherein the input stage circuit comprises a first inverter and a second inverter that are in cascade connection and driven by a power voltage of a relatively low level,
the input signal is input to the first inverter,
an output signal of the first inverter is input to the second inverter and the first transistor,
an output signal of the second inverter is input to the second transistor,
the output stage circuit comprises a third inverter driven by a power voltage of a relatively high level, and
a signal generated at a connection point between the second transistor and the second switch circuit is input to the third inverter.
